(19) United States
(12) Patent Application Publication
(10) Pub. No.: US 2007/0254102 A1
(43) Pub. Date: Nov. 1, 2007

(54) Method for producing SiOx (x < 1)

(75) Inventors: Hirofumi Fukuoka, Annaka-shi (JP); Mikio Aramata, Annaka-shi (JP); Satoru Miyawaki, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd.

(21) Appl. No.: 11/790,234

(22) Filed: Apr. 24, 2007

(30) Foreign Application Priority Data
Apr. 26, 2006 (JP) 2006-121954

(51) Int. Cl. C23C 14/10

(52) U.S. Cl. 427/255.27

(57) ABSTRACT

A method for producing a SiOₓ (x<1) is provided. The SiOₓ produced is adapted for use as an anode material in producing a lithium ion secondary battery having a large capacity which does not experience degradation with repeated cycles of use, and which has low irreversible capacity in the initial charge and discharge.

The method for producing a SiOₓ (x<1) comprises the steps of heating a starting material which generates a silicon oxide gas to a temperature in the range of 1,100 to 1,600° C. in the presence of an inert gas or under a reduced pressure to produce the silicon oxide gas, while heating is metal silicon to a temperature in the range of 1,800 to 2,400° C. in the presence of an inert gas or under a reduced pressure to generate silicon gas, and precipitating the gas mixture of the silicon oxide gas and the metal silicon gas on a surface of a substrate.

### CROSS-REFERENCE TO RELATED APPLICATION

This non-provisional application claims priority under 35 U.S.C. §119(a) on Patent Application No. 2006-121954 filed in Japan on Apr. 26, 2006, the entire contents of which are hereby incorporated by reference.

### TECHNICAL FIELD

This invention relates to a method for producing SiOₓ (x<1) which is effective for use as an anode material of a lithium ion secondary battery.

### BACKGROUND OF THE INVENTION

With the amazing development in the mobile electronic equipment and communication equipment, there is a strong request for a secondary battery having a higher energy density in view of improving-economic efficiency and reducing the size and weight of the equipment. Increase in the capacity of the secondary batteries has been realized, for example, by incorporating an oxide of V, Si, B, Zr, Sn, and the like or a mixture thereof in the anode material (for example, JP-A 5-174818, JP-A 6-60867 corresponding to U.S. Pat. No. 5,478,671: Patent Documents 1 and 2), by applying a molten and quenched metal oxide as the anode material (JP-A 10-294112: Patent Document 3), by using silicon oxide for the anode material (Japanese Patent No. 2997741 corresponding to U.S. Pat. No. 5,935,711: Patent Document 4), and by using Si₂N₂O and Ge₂N₂O for the anode material (JP-A 11-102705 corresponding to U.S. Pat. No. 6,066,414: Patent Document 5).

However, while these prior art attempts have been effective in improving the charge and discharge capacity as well as the energy density, they were not necessarily satisfactory in retaining their performance in repeated cycles of use or fulfilling the market's requirements, and accordingly, further increase in the energy density is demanded.

Among the attempts as described above, use of silicon oxide for the anode material (Japanese Patent No. 2997741: Patent Document 4) succeeded in realizing a lithium ion secondary battery having an improved battery property, and further increase in the capacity is awaited.

### SUMMARY OF THE INVENTION

The present invention has been completed in view of the situation as described above, and an object of the present invention is to provide an SiOₓ (x<1) which is adapted for use as an anode material in producing a lithium ion secondary battery having a large capacity which does not experience degradation with repeated cycles of use, and which has low irreversible capacity in the initial charge and discharge.

The inventors of the present invention have made an intensive study to realize the object as described above, and by attempting to further increase the capacity by using silicon oxide which was deemed to have a latent ability of realizing such increase in the capacity, the inventors found that a lithium ion secondary battery having a large capacity which does not experience degradation with repeated cycles of use, and which has low irreversible capacity in the initial charge and discharge can be produced by dispersing and doping metal silicon in the silicon oxide to produce an SiOₓ (x<1) with reduced oxygen and using this SiOₓ (x<1) for the anode material. The present invention has been completed on the bases of such finding.

Accordingly, the present invention provides a method for producing SiOₓ (x<1) as described below.
[1] A method for producing a SiOₓ (x<1) comprising the steps of heating a starting material which generates a silicon oxide gas to a temperature in the range of 1,100 to 1,600° C. in the presence of an inert gas or under a reduced pressure to produce the silicon oxide gas, while heating metal silicon to a temperature in the range of 1,800 to 2,400° C. in the presence of an inert gas or under a reduced pressure to generate silicon gas, and precipitating the gas mixture of the silicon oxide gas and the metal silicon gas on a surface of a substrate.
[2] The method for producing a SiOₓ according to the above [1] wherein the value of x in the SiOₓ (x<1) is 0.3<x<0.9.
[3] The method for producing a SiOₓ according to the above [1] or [2] wherein the starting material which generates the silicon oxide gas is a mixture of a silicon oxide powder or a silicon dioxide powder with a metal silicon powder.

### EFFECTS OF THE INVENTION

A lithium ion secondary battery having a large capacity which has excellent initial charge and discharge efficiency and which does not experience degradation with repeated cycles of use can be produced by using the SiOₓ (x<1) produced by the method of the present invention.

### BRIEF DESCRIPTION OF THE DRAWINGS

FIG. 1 is a schematic view showing the production system used in the Examples of the present invention for producing the SiOₓ.

### DETAILED DESCRIPTION OF THE INVENTION

In the method for producing SiOₓ (x<1) of the present invention, a mixture of silicon oxide or silicon dioxide powder and a powder of a material which reduces the silicon oxide or silicon dioxide powder is used for the starting material used for generating silicon oxide gas. Examples of such reducing powder include metal silicon compounds and carbon-containing powders, and among these, use of the one containing a metal silicon powder is preferable in view of (1) increasing the reactivity, and (2) increasing the yield.

The metal silicon powder and the silicon dioxide powder may be mixed at an adequately selected ratio. However, they may be mixed at a mixing ratio of 1<metal silicon powder/silicon dioxide powder<1.1, and in particular, 1.01≦metal silicon powder/silicon dioxide powder≦1.08 in consideration of the oxygen on the surface of the metal silicon powder and the presence of a minute amount of oxygen in the reaction furnace.

In the present invention, the starting material which generates the silicon oxide gas as described above is heated and maintained at a temperature of 1,100 to 1,600° C., and preferably 1,200 to 1,500° C. to thereby generate silicon oxide gas. When the reaction temperature is lower than 1,100° C., the reaction will not sufficiently proceed to detract from the productivity, whereas the reaction at a temperature in excess of 1,600° C. results in the melting of the starting powder mixture, and hence, in the decrease of reactivity and difficulty of selecting the furnace material.

This reaction is conducted by using an inert gas for the furnace atmosphere or at a reduced pressure. From the thermodynamic point of view, a higher reactivity can be attained by the use of a reduced pressure, and the reaction can also be carried out at a lower temperature. Accordingly, the reaction is generally carried out at a pressure of 1 to 100 Pa, and in particular, at 5 to 100 Pa.

In the meanwhile, the metal silicon is heated and retained at a temperature of 1,800 to 2,400° C., and preferably 2,000 to 2,300° C. to generate the metal silicon gas. When the reaction temperature is less than 1,800° C., generation of the metal silicon gas is insufficient and production of the intended SiOₓ (x<1) will be difficult. Heating to a temperature in excess of 2,400° C. or higher is associated with difficulty in selecting the furnace material.

This reaction is conducted by using an inert gas for the furnace atmosphere or at a reduced pressure. From the thermodynamic point of view, a higher reactivity can be attained by the use of a reduced pressure, and the reaction can also be carried out at a lower temperature. Accordingly, the reaction is generally carried out at a pressure of 1 to 100 Pa, and in particular, at 5 to 100 Pa.

The value of x in the SiOₓ of the present invention is x<1, and this value can be controlled by the temperature to which the starting material generating the silicon oxide gas and the metal silicon are heated, namely by the vapor pressure of these components, and the weight of the starting material generating the silicon oxide gas and the metal silicon. In the present invention, the value of x in the SiOₓ is preferably in the range of 0.3<x<0.9, more preferably 0.4≦x≦0.8, and most preferably 0.4<x<0.8. When the value of x is 0.3 or less, the cell may become deteriorated with repeated cycles of use while cell capacity and initial irreversible capacity are reduced. On the other hand, when the value of x is 0.9 or higher, the capacity of the level required by the market may not be satisfied.

When the value of x in the SiOₓ is within such range, the value of x can be controlled by the vapor pressure and the amount of each of the starting material generating the silicon oxide gas and the metal silicon. More specifically, when the vapor pressure of the starting material generating the silicon oxide gas and the metal silicon is the same and these components are used at the same amount, the value of x is theoretically 0.5. The vapor pressure of the starting material generating the silicon oxide gas and the metal silicon is determined by the temperature to which they are respectively heated, and for example, the vapor pressure of the starting material generating the silicon oxide gas heated to a temperature of 1350° C. and the vapor pressure of the metal silicon heated to a temperature of 2200° C. are at the same level, namely, at 500 Pa.

The starting material generating the silicon oxide gas and the metal silicon may be mixed at an adequate mixing ratio depending on the desired value of x. However, since Si is heated to a higher temperature, a higher efficiency can be realized when Si is used at a higher mixing ratio. More specifically, the starting material generating the silicon oxide gas and the metal silicon may be mixed at a weight ratio of the starting material generating the silicon oxide gas/the metal silicon of 1/5 to 1/1, and in particular, 1/3 to 1/1.5.

The production system used in the production of the present invention is not particularly limited, and the production system may be the one having the mechanism of generating the silicon oxide gas and the mechanism of generating the metal silicon gas separately, or the one having such mechanisms in the same apparatus. Also, the method used in mixing the generated silicon oxide gas and the metal silicon gas is not particularly limited.

The type of the substrate used for the precipitation of the gas mixture is not particularly limited. The preferred, however, is a metal having a high melting point such as SUS and tungsten.

The conditions used in precipitating the gas mixture on the substrate are not particularly limited, and the precipitation can be accomplished by statically placing the substrate on the gas flow passage. However, homogeneous precipitation of the gas mixture on the substrate may be facilitated by constituting the substrate from a relatable body, or by passing a cooling medium such as water through the substrate.

The SiOₓ (x<1) precipitated on the substrate may be collected by an adequate means such as scraping. The collected SiOₓ may be pulverized by an adequate means to the desired particle size.

The SiOₓ (x<1) produced in the present invention may be used for the anode material in producing a lithium ion secondary battery.

The lithium ion secondary battery produced in the present invention has the characteristic feature that it is produced by using the material as described above for the anode active material, and other factors of the battery, for example, the material used for the cathode, anode, electrolyte, separator, and the like and the shape of the battery are not particularly limited. For example, exemplary materials which may be used for the cathode active material include transition metal oxides such as LiCoO₂, LiNiO₂, LiMn₂O₄, V₂O₆, MnO₂, TiS₂, and MoS₂ and chalcogen compounds. Exemplary electrolytes include non-aqueous solution containing a lithium salt such as lithium perchlorate, and exemplary non-aqueous solvents include propylene carbonate, ethylene carbonate, dimethoxy ethane, γ-butyrolactone, and 2-methyl tetrahydrofuran, which may be used alone or in combination of two or more. Various other non-aqueous electrolytes and solid electrolytes may also be used.

The SiOₓ powder of the present invention may be used by adding an electroconductive agent such as graphite, and the electroconductive agent used is not particularly limited as long as it is an electron-conductive material which does not experience decomposition or deformation in the resulting battery. Exemplary such electroconductive agents include powders or fibers of a metal such as Al, Ti, Fe, Ni, Cu, Zn, Ag, Sn, or Si, various forms of graphite such as natural graphite, artificial graphite, various coke breezes, mesophase carbon, gas phase-grown carbon fibers, pitch carbon fibers, PAN carbon fibers, and various sintered resins.

### EXAMPLES

Next, the present invention is described in detail by referring to Examples of the present invention and Comparative Examples, which by no means limit the scope of the present invention. In the following Examples and Comparative Examples, the average particle size is the cumulative weight average (D₅₀) calculated in the measurement of particle size distribution by laser diffractometry.

### Examples 1 to 3 and Comparative Examples 1 and 2

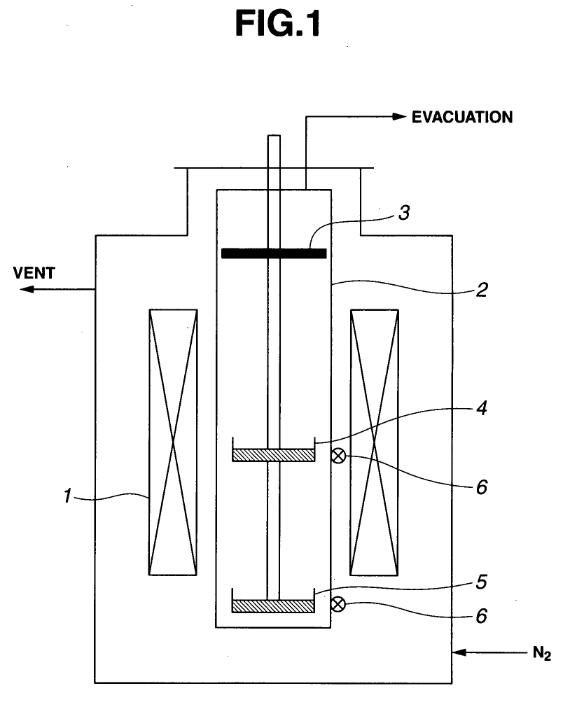

The SiOₓ was produced by using the production system shown in FIG. 1. Silicon oxide powder (325#PASS) of the amount shown in Table 1 was placed in a second material tray (5) as a starting material generating the silicon oxide gas, and metal silicon powder of the amount shown in Table 1 was placed in a first material tray (4). The material trays had been inserted in a reaction tube (2) having a diameter of 80 mm. Next, the interior of the furnace was evacuated to a pressure of up to 0.1 Torr by using a vacuum pump, and using a heater (1), the first material tray (4) was heated and retained at an elevated temperature of 2,200° C., while the second material tray (5) was heated and retained at a temperature of 1,430° C. After continuing this operation for 5 hours, the temperature was reduced to room temperature for precipitation of the gas on the substrate (3). In FIG. 1, “6” stands for a thermocouple.

Next, 30 g of this intermediate was pulverized by wet pulverization in a 2 L alumina ball mill using 1,000 g of alumina balls having a diameter of 5 mm for the medium and 500 g of hexane for the solvent under the rotation condition of 1 rpm. The pulverized SiOₓ powder had the physical properties as shown in Table 1.

### [Evaluation of the Battery]

Next, a battery was produced by using such SiOₓ powder for the anode active material, and this battery was evaluated by the procedure as described below.

First, 45% by weight of an artificial graphite having an average particle diameter of 5 μm and 10% by weight of polyvinylidene fluoride were added to the SiOₓ powder produced as described above, and after adding N-methyl pyrrolidone to produce a slurry, this slurry was applied to a copper foil having a thickness of 20 μm. After drying at 120° C. for 1 hour, an electrode was pressed at an elevated pressure in a roller press, and an anode of 2 cm² was finally punched from this sheet.

In order to evaluate the charge and discharge characteristics of the resulting anode, a secondary battery for evaluation purpose was prepared by using a lithium foil for the counter electrode, a non-aqueous electrolyte solution of lithium hexafluorophosphate in a 1/1 (volume ratio) mixture of ethylene carbonate and dimethyl carbonate for the non-aqueous electrolyte, and a polyethylene microporous film having a thickness of 30 μm for the separator.

The thus produced lithium ion secondary battery was allowed to stand overnight at room temperature, and, placed in a secondary battery charge and discharge tester manufactured by Nagano. The test cell was charged at a constant current of 1 mA until the voltage of the test cell reached 0 V, and after reaching 0 V, the cell was charged by reducing the current so that the cell voltage would remain at 0 V. The charging was terminated when the current value reduced to less than 20 μA. The discharge was conducted at a constant current of 1 mA, and the discharge was terminated when the cell volgate exceeded 1.8 V, and discharge capacity was measured.

The lithium ion secondary battery prepared as described above for evaluation was evaluated for its discharge capacity after 10 cycles of such charge and discharge cycles. The results are shown in Table 1.

TABLE 1

| | | Amount | | Physical | | | | | |
|---|---|---|---|---|---|---|---|---|---|
| | | of the | | properties | | Test results of the battery | | | |
| | | starting | | of the | | | | Discharge | |
| | | materials | | SiOₓ | | Initial | Initial | capacity | |
| | | used (g) | | powder | | charge | discharge | after | Capacity |
| | | Silicon | Metal | value | D₅₀ | capacity | capacity | 10 cycles | retention |
| | | oxide | silicon | of x | (mm) | (mAh/g) | (mAh/g) | (mAh/g) | (%) |
| Example | 1 | 30 | 30 | 0.63 | 6.2 | 1620 | 1430 | 1410 | 98.6 |
| | 2 | 30 | 20 | 0.75 | 6.5 | 1510 | 1340 | 1320 | 98.5 |
| | 3 | 30 | 10 | 0.88 | 6.8 | 1440 | 1290 | 1280 | 99.2 |
| Comparative | 1 | 30 | 0 | 1.05 | 6.3 | 1310 | 920 | 910 | 98.9 |
| Example | 2 | 0 | 30 | 0.02 | 6.6 | 1980 | 1810 | 670 | 37.0 |

Japanese Patent Application No. 2006-121954 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for producing a SiOₓ (x<1) comprising the steps of heating a starting material which generates a silicon oxide gas to a temperature in the range of 1,100 to 1,600° C. in the presence of an inert gas or under a reduced pressure to produce the silicon oxide gas, while heating metal silicon to a temperature in the range of 1,800 to 2,400° C. in the presence of an inert gas or under a reduced pressure to generate silicon gas, and precipitating the gas mixture of the silicon oxide gas and the metal silicon gas on a surface of a substrate.

2. The method for producing a SiOₓ according to claim 1 wherein the value of x in the SiOₓ (x<1) is 0.3<x<0.9.

3. The method for producing a SiOₓ according to claim 1 wherein the starting material which generates the silicon oxide gas is a mixture of a silicon oxide powder or a silicon dioxide powder with a metal silicon powder.
